(19) United States
(12) Patent Application Publication
(10) Pub. No.: US 2025/0308969 A1
(43) Pub. Date: Oct. 2, 2025

(54) MULTI-MODAL ELECTROSTATIC CHUCKING

(71) Applicant: Lam Research Corporation, Fremont, CA (US)

(72) Inventors: Noah Elliot Baker, West Linn, OR (US); Ramesh Chandrasekharan, Lake Oswego, OR (US); Karl Frederick Leeser, West Linn, OR (US)

(21) Appl. No.: 18/861,554

(22) PCT Filed: May 2, 2023
(86) PCT No.: PCT/US2023/020686

§ 371 Date: Oct. 29, 2024

Related U.S. Application Data
(60) Provisional application No. 63/364,330, filed on May 6, 2022.

(51) Int. Cl. H01L 21/683; H01J 37/32

(52) U.S. Cl. CPC H01L 21/6833; H01J 37/32183; H01J 37/32715

(57) ABSTRACT

Multi-modal electrostatic chuck (ESC) apparatus, and systems and methods for operating an ESC are provided. In some embodiments, the ESC may operate in monopolar clamping mode or bipolar clamping mode. In some embodiments, the ESC may utilize a pair of electrodes for the monopolar and bipolar clamping mode. In some embodiments, each of the pair of electrodes may be electrically coupled to a respective power source. In some embodiments, the ESC may be operated in a first clamping mode (e.g., bipolar clamping mode), and based at least on a change in a processing environment, operated in a second clamping mode (e.g., monopolar clamping mode).

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor processing tools commonly include one or more semiconductor processing chambers that provide an isolated environment within which to process semiconductor wafers. Semiconductor processing tools may be used to perform plasma-based processing operations on semiconductor wafers. Plasma sources are used to create a plasma that, when a process gas is flowed into them, creates neutral particles, ions, and/or radicals of the process gas. These particles may then be flowed to react physically and/or chemically with a substrate of interest, such as the semiconductor wafer. In some semiconductor processing tools, multiple semiconductor wafers may be processed within a single chamber. In such semiconductor processing tools, such a chamber may include one or more wafer processing stations, each having its own wafer support or pedestal. In some designs, the pedestal may be an electrostatic chuck (ESC) on which the substrate rests. The ESC or pedestal may be used to generate an electromagnetic field that may clamp the substrate to the ESC and/or bias particles to the ESC. ESCs are frequently used during semiconductor fabrication to grip or clamp a wafer undergoing fabrication so as to mitigate deformation or bow during the fabrication process.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

In one aspect of the present disclosure, a system configured to operate an electrostatic chuck (ESC) in a plurality of modes is disclosed. In some embodiments, the system includes: a plurality of clamping electrodes associated with the ESC, a plurality of power sources electrically coupled to the plurality of clamping electrodes; a controller coupled to the plurality of power sources, wherein the controller is configured to: clamp a substrate to the ESC using a first clamping mode, the first clamping mode comprising a first configuration of the plurality of clamping electrodes and the plurality of power sources; and during operation of the ESC using the first clamping mode, switch from the first clamping mode to clamp the substrate to the ESC using a second clamping mode, the second clamping mode comprising a second configuration of the plurality of clamping electrodes and the plurality of power sources, the second configuration being different from the first configuration

In another aspect of the present disclosure, a method of operating an electrostatic chuck (ESC) in multiple modes is disclosed. In some embodiments, the method includes: operating the ESC in a first clamping mode; and during a portion of the operation in the first clamping mode, and based on a change in a processing environment, operating the ESC in a second clamping mode.

In some variants thereof, each of the first clamping mode and the second clamping mode comprises clamping a substrate to the ESC using respective configurations of clamping electrodes associated with the ESC.

In another aspect of the present disclosure, an electrostatic chuck (ESC) operable in a substrate processing environment is disclosed. In some embodiments, the ESC includes: a first clamping electrode electrically coupled to a first power source; and a second clamping electrode electrically coupled to a second power source; wherein the ESC is configured to: clamp a substrate to the ESC using a first clamping mode; and during a portion of the first clamping mode, switch to clamp the substrate to the ESC using a second clamping mode.

In some variants thereof, the first clamping mode comprises a first voltage received at the first clamping electrode from the first power source, and a second voltage received at the second clamping electrode from the second power source, the first and second voltage having opposing polarities.

In some other variants thereof, the second clamping mode comprises a voltage received at the first clamping electrode from the first power source and the second clamping electrode from the second power source.

In another aspect of the present disclosure, a non-transitory computer-readable apparatus is disclosed. In some embodiments, the computer-readable apparatus includes a storage medium comprising a plurality of instructions configured to, when executed by at least a processor, cause an electrostatic chuck (ESC) to: clamp a substrate to the ESC using a first clamping mode; and during a portion of the first clamping mode, switch to clamp the substrate to the ESC using a second clamping mode.

These and other features of the disclosed embodiments will be described in detail below with reference to the associated drawings.

### BRIEF DESCRIPTION OF DRAWINGS

FIG. 1 is a block diagram illustrating a side view of a process chamber, according to some embodiments.

FIGS. 2A-2C are illustrations of example configurations of electrode pairs, according to some embodiments.

FIGS. 3A and 3B are block diagrams illustrating configurations of electrical coupling of electrodes of an ESC and power sources, according to some embodiments.

FIGS. 4A and 4B are circuit diagrams illustrating configurations of power sources, according to some embodiments.

FIGS. 4C and 4D are circuit diagrams illustrating configurations of power sources and high-voltage (HV) switches, according to some embodiments.

FIG. 5A is an example timing sequence diagram showing activation states of an ESC using a multi-modal configuration, according to some embodiments.

FIG. 5B is an example timing sequence diagram showing activation states of an ESC using a multi-modal configuration, according to some embodiments.

FIG. 6 is a flow diagram illustrating a method for operating an ESC, according to some embodiments.

FIG. 7 is a flow diagram illustrating another method for operating an ESC, according to some embodiments.

FIG. 8 is a flow diagram illustrating another method for operating an ESC, according to some embodiments.

### DETAILED DESCRIPTION

This disclosure relates to electrostatic chucks (ESC) used in semiconductor processing. In semiconductor processing equipment, an electrostatic chuck is commonly used for clamping a substrate to a pedestal during a plasma process. The electrostatic chuck may be configured to clamp the substrate by creating an attractive force between the substrate and the chuck. A chucking voltage may be applied to one or more electrodes in the ESC to induce oppositely polarized charges in the substrate and the electrodes, respectively. In some cases, the electrodes may also be referred to as “grids.” Various designs may be used to accomplish clamping.

Semiconductor device fabrication often involves deposition of a stack of layers on a wafer substrate. Typically, most deposition and other processing to form the devices occurs on one or more sides of the substrate. As the deposited layers build up, they can introduce stress in the wafer. A large net compressive or tensile stress can cause the wafer to bow, in which a deviation occurs from a plane of a substrate (e.g., median plane of a semiconductor wafer), which is undesirable. Such wafers can be highly sensitive to such deviations. Dimensions of features (e.g., traces, circuits) fabricated on a wafer may become easily distorted based on slight positioning or bowing deviations of the wafer, as features (which can reach the nanometer scale) can require precise processing. Moreover, wafers are typically thin and susceptible to internal stress or tensile/compressive stress, especially during fabricating processes (deposition, etching, heating, layering, etc.).

Further, certain processing steps (e.g., photolithography) are very precise and can produce poor results if the wafer is not substantially flat. The problem may be manifest as lithography defocus. One example stack that may cause these problems is a stack having alternating layers of oxide and nitride (e.g., silicon oxide, silicon nitride, silicon oxide, silicon nitride). Another example stack likely to cause bowing includes alternating layers of oxide and polysilicon (e.g., silicon oxide, polysilicon, silicon oxide, polysilicon). Other examples of stack materials that may be problematic include, but are not limited to, tungsten and titanium nitride. The materials in the stacks may be deposited through chemical vapor deposition techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting.

Various techniques have been devised to combat bowing. Many such techniques involve tuning deposition processes to reduce or counteract internal stresses in deposited layers. One such technique is electrostatic chucking, which may be conducted in a manner that reduces or eliminates bowing (e.g., a clamped wafer exhibits less than about 150 μm of bow). Apparatus known as an electrostatic chuck (ESC) may be useful for counteracting bowing. Clamping using ESCs to hold the substrate or wafer in place can result in consistent and precise fabrication of features.

Multiple variations and configurations of ESCs exist. In a monopolar ESC having one clamping electrode, the one electrode may have a voltage applied thereto, and an opposite charge may be induced in the substrate using, e.g., a plasma generated above the substrate. As such, a clamping force may be exerted against the plasma-induced bias on the substrate.

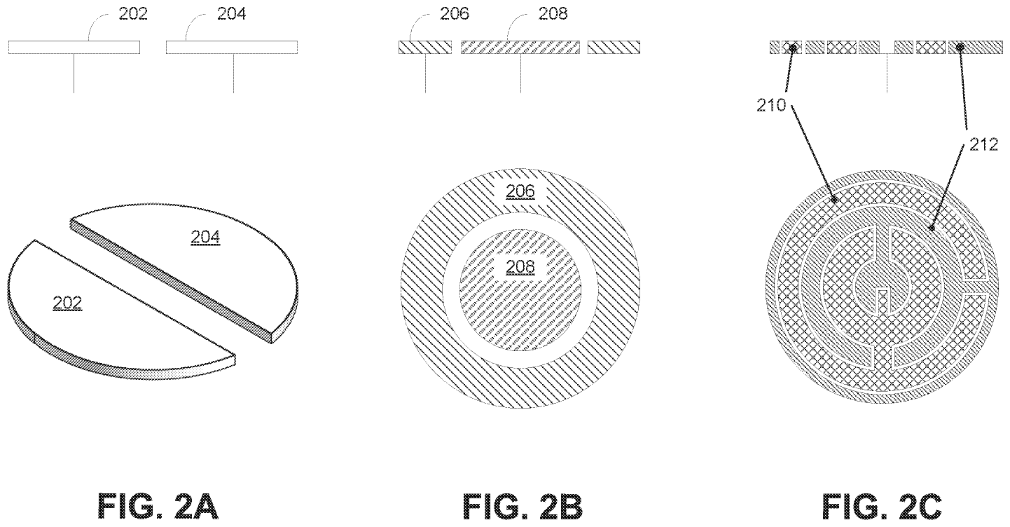

In a bipolar ESC, the electrostatic chuck has a pair of complementary and coplanar clamping electrodes, which may be embedded within a pedestal structure. An electrode may be respectively connected to a terminal of a power supply, or multiple power supplies in some embodiments, or to another system configured to apply an electrical potential to the electrodes. Here, force may be exerted between the pair of complimentary electrodes, one positive and one negative, to the substrate. The electrodes may be positioned such that they are underneath a wafer placed upon the substrate. The opposite charges may interact with the substrate, in particular a bottom surface of the substrate, to pull the substrate against the electrostatic chuck, thus clamping the substrate to the chuck. In some embodiments, one or more of the clamping electrodes may be “D-shaped.” However, myriad other electrode shapes may be used, including interdigitated clamping electrodes or concentric clamping electrodes, as shown in FIGS. 2A-2C.

In some cases, an ESC may include more than two electrodes. For example, in a tripolar or a multipolar ESC, voltage may be applied between a plethora of electrodes (e.g., three or more) such that time-averaged substrate bias in a particular region of the substrate remains zero, or controlled to a setpoint, e.g., a desired or target bias value.

Monopolar clamping requires plasma to be present (e.g., in a process chamber used with the ESC) before the substrate (e.g., a wafer) can be clamped. This can in some cases cause high-bow wafers to not clamp or not fully clamp as the plasma discharges from the surface before the wafer can be flattened. Moreover, bowing may be reintroduced (to an otherwise planar wafer) when plasma strength diminishes or shuts off.

Bipolar clamping can occur with or without the presence of plasma, which obviates the declamping risks associated with monopolar clamping, and may also be insensitive to wafer topside films. However, for some film and wafer types (e.g., carbon deposition processes and some ALD applications), bipolar clamping can cause the targeted deposition processes to have azimuthal nonuniformity associated with the relative polarity, resulting in a “potato chip” surface. Also, bipolar clamping can in some cases cause preferential damage to chamber components or parasitics (gases that have been excited into an unwanted plasma) that can affect the repeatability of the processes. Tripolar or multipolar alternating current (AC) clamping may resolve the foregoing risks associated with bipolar clamping. However, multipolar configurations involve more electrodes (e.g., three or more), higher power and/or more costly components (e.g., power source), and tighter thermal operating limits for the pedestal to be operated in the Johnsen-Rahbek (JR) region.

Thus, it is desired to configure electrostatic chucks to take advantage of aforementioned respective benefits of monopolar and bipolar clamping depending on the application and processing conditions (e.g., presence of plasma).

The following terms are used throughout the present specification:

An “electrostatic chuck” (ESC) as used herein refers to a chuck that uses electrostatic force to clamp a wafer to the chuck during processing. The ESC may use one or more electrodes. Voltages may be applied to the one or more electrodes. The applied voltage may cause current to flow, thereby causing charge to migrate through a dielectric layer between the chuck and a wafer or substrate being processed. Opposite charges accumulated at an electrode relative to the wafer therefore cause the wafer to be gripped or clamped to the chuck by the electrostatic force. In some cases, the electrodes may be integrated into the ESC, or may be separate from the ESC. In some embodiments, the ESC may refer to the electrodes that generate the electrostatic force.

In some embodiments, the ESC may employ the plasma in a circuit. In some embodiments, the ESC may employ multiple electrodes that concurrently apply different polarity potentials to the substrate. In particular, in some embodiments, the ESC may be bipolar, as discussed above. In some embodiments, the ESC may be monopolar, as discussed above. In some embodiments, the ESC may be tripolar or multipolar (having three or more electrodes).

A “platen” as used herein refers to a top surface of an ESC on which a wafer undergoing fabrication is positioned. There may be a gap between the wafer and the platen surface (e.g., the upper surface), which is generally referred to herein as “d.”

A “pedestal” as used herein may refer to a structure or housing that supports, or includes, the platen.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The work piece may be of various shapes, sizes, and materials.

A “semiconductor device fabrication operation” as used herein is an operation performed during fabrication of semiconductor devices. As referred to herein, such a fabrication operation is sometimes simply referred to as a “process” or as “processing.” Examples of processing include deposition of a material on a substrate, selectively etching material from a substrate, and ashing of photoresist on a substrate. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

As referred to herein, manufacturing equipment is sometimes simply referred to as a “process chamber.” In various embodiments, a process chamber is typically a sealed enclosure in which a substrate is immobilized during processing. The process chamber may include components associated with delivery of and removal of gases. It may also include components associated with generating a plasma and controlling properties of the plasma within the chamber. It may include components for controlling the pressure, including pulling a vacuum within the chamber. In the context of this disclosure, the process chamber may include a pedestal on which the substrate sits while it is being processed. A pedestal may be outfitted with a chuck such as an ESC to hold the wafer in position during processing.

“Wafer bow” as used herein may refer to a deformation of a wafer. Wafer bow may occur during fabrication, for example, as a result of stress to the wafer during deposition of materials on an active surface of a wafer substrate. Wafer bow may occur during various types of fabrication, such as when large stacks of materials are deposited. Wafer bow may cause complications in subsequent processing steps. For example, the wafer may fail to chuck correctly if an amount of bowing is too large. Moreover, some processing steps (e.g., photolithography) may produce poor results if performed on a wafer that is excessively bowed.

Wafer bow may be measured as a deviation of the mean or median distance of the surface of the wafer to a reference plane. The point of the median surface of the wafer may be the center point (e.g., in the case of concave or domed bowing), or an edge point of the wafer and/or an average edge point of the wafer (e.g., in the case of warping or convex bowing).

“Wafer declamping” as used herein refers to a state where a wafer is no longer clamped to a platen of an electrostatic chuck (ESC). As used herein, when wafer bow is detected, or more than a threshold amount of wafer bow is detected, during fabrication or processing of a wafer, the wafer can be considered declamped from the ESC. It should be noted that, as used herein, wafer bow may be associated with a numeric value that indicates a degree of bowing. By contrast, wafer declamping may be a binary classification that indicates whether or not a wafer is clamped to the platen.

A “power source” as used herein may refer to an apparatus or a system that provides power to another apparatus or portion of the system. In some embodiments, A power source may provide direct current (DC) and/or radio frequency (RF) power to one or more electrodes. In some implementations, alternating current (AC) may be received at the power source and converted to DC. In some implementations, a desired voltage may be selected for provision by the power source. In some embodiments, a system may include or be associated with multiple power sources. In some implementations, a first power source may be associated with (e.g., configured to provide power to) one electrode, and a second power source separate from the first one may be associated with (e.g., configured to provide power to) a second electrode. In some embodiments, a power source may be electrically coupled to at least one controller configured to determine operational parameters for the power source and/or the electrode(s) powered by the power source, and provide signals to the power source to cause the power source to provide power according to the operational parameters. Examples of such operational parameters include voltage, power, and current provided by the power source.

In some embodiments, a power source may include or be associated with an internal switch or an external switch that can toggle the flow of current from one or more power sources. A switch may toggle usage between at least one power source to at least one other power source. In some cases, the switch may toggle an electric path between one power source to multiple power sources. A power supply or power supply unit (PSU) may be an example of such a power source. A power supply may be rated at a wattage that would provide power suitable for usage with the system, e.g., to provide desired power to one or more electrodes.

### Electrostatic Chuck Operating Modes

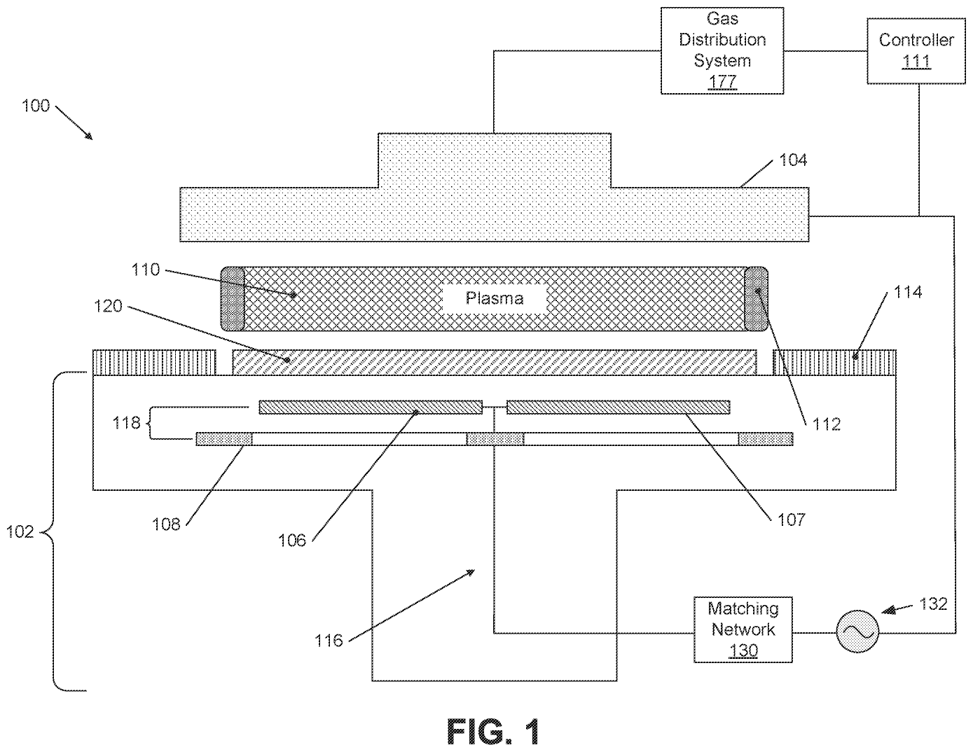

FIG. 1 is a block diagram illustrating a side view of a process chamber 100, according to some embodiments. The process chamber 100 may be used in conjunction with systems or components used for various plasma processing techniques, such as plasma-enhanced chemical vapor deposition (PECVD), plasma etching, plasma stripping or ashing, sputtering, plasma spraying, and the like. The process chamber 100 may include an electrostatic chuck (ESC) 102 configured to support a substrate 120 (e.g., a wafer). An ESC may herein also be referred to as a “pedestal.” In some embodiments, ESC 102 may comprise a collection of electrodes 118, which may include clamping electrodes 106 and 107 and/or a blocking electrode 108. The blocking electrode 108 and clamping electrodes 106, 107 may have one or more electrical leads 116 that are configured to electrically connect, either directly or indirectly, the electrodes to at least one RF power supply 132, which may provide direct current (DC) and/or radio frequency (RF) power to the electrodes.

In some implementations, the clamping electrodes 106, 107 and/or the blocking electrodes 108 may be a thin sheet of electrically conductive material, e.g., metal, machined to have shapes as described herein. In some implementations, an electrode may have multiple components. In some implementations, the electrodes may have slots or holes or be made of a mesh that allow the movement of particles therethrough; this may reduce the risk of delamination after sintering, as the ceramic particles may sinter through the electrodes rather than merely around them. In some implementations, the electrodes may be a metallic mesh, e g., a woven mesh having multiple metal strands that overlap and are electrically connected. Regardless of the particular details of the electrode material, the electrodes may be machined into shapes such as are discussed herein.

As noted elsewhere above, a bipolar electrostatic chuck (as opposed to a monopolar electrostatic chuck) includes two clamping electrodes, such as clamping electrodes 106 and 107 as depicted in FIG. 1. The clamping electrodes 106 and 107 may have opposite voltages (e.g., −500 V and +500 V) to pull the substrate 120 against the ESC 102, thereby clamping the substrate to the ESC 102.

It is noted, however, that the two clamping electrodes 106 and 107 may not necessarily have opposing voltages, and instead, may have identical voltages. Advantageously, such a configuration in which two electrodes may receive the same or opposing voltages allows operation of the ESC in a monopolar mode and a bipolar mode, which will be discussed in greater detail below.

Returning to FIG. 1, generally, the blocking electrode 108 (also known as an “outer electrode,” “edge electrode,” or “averaging electrode”) may improve the uniformity of processing operations performed on the substrate. In some embodiments, the blocking electrode 108 may also extend around the clamping electrodes 106, 107. In some embodiments, the blocking electrode 108 may have an annular shape or an annular portion associated with the blocking electrode 108. In some implementations, the annular portion, when viewed from above, may encircle the clamping electrodes 106, 107. The blocking electrode may average anomalies associated with the positive and negative polarities of the clamping electrodes, smoothing the interaction of the clamping electrodes with the wafer. The blocking electrode may also interact with a plasma above the wafer during wafer processing operations to improve processing uniformity. More specifically, RF power provided to the blocking electrode 108 may control the area where a plasma forms, particularly the radius of the plasma. As plasma processes may have non-uniformities from center-to-edge resulting from the plasma, the RF power delivered to the blocking electrode 108 and the clamping electrodes 106, 107 may be tuned to control the plasma and improve uniformity.

In some embodiments, ESC 102 may be configured to support a substrate 120 that may be provided to a substrate processing environment, e.g., the process chamber 100. The substrate 120, which may also be referred to as a substrate or semiconductor substrate, may be a silicon-based or other semiconductor wafer, e.g., a 200-mm wafer, a 300-mm wafer, or a 450-mm wafer, including wafers having one or more layers of material, such as dielectric, conducting, or semi-conducting material, deposited thereon. It should be understood that the process chamber 100 and ESC 102 described herein may be designed for a 300-mm wafer in one embodiment. Suitable modifications may be made to scale various elements for larger or smaller wafers (e.g., the electrodes may be scaled to correspond with the wafer diameter to be processed).

In some embodiments, a ring 114, e.g., an edge ring or exclusion ring, may also be positioned on the ESC 102. In some implementations, ring 114 may be a ceramic ring placed so as to protect, e.g., the pedestal/ESC in the process chamber from damage from the plasma and/or may assist in controlling the plasma. In some implementations, ring 114 may be a replaceable component.

In some embodiments, a showerhead 104 may be positioned above the ESC 102. During processing operations, process gases may be flowed through the showerhead 104 toward the substrate 120. In some embodiments, a plasma 110 may be formed above the substrate 120 during operation. In some embodiments, the showerhead 104 may include or otherwise be coupled to a plasma generation system (not shown) that may be used to generate a plasma. Showerhead 104 (or a plasma generator system) and ESC 102 (including the clamping electrodes and blocking electrode) may be electrically coupled to an RF power supply 132 and a matching network 130 for powering a plasma. During operation, RF power supply 132 and matching network 130 may be operated at any suitable power to form a plasma having a desired composition of species. Plasma 110 may have a plasma edge region 112 that is positioned proximate the outer edge of the substrate 120.

In some embodiments, to control a manner in which the RF power supply 132 operates, the controller 111 may be operatively coupled therewith. The controller 111 may be an analog controller, a discrete logic controller, a programmable array controller (PAL), a programmable logic controller (PLC), a microprocessor, a computer, or any other device capable of carrying out operations for effecting processing operations. In some exemplary embodiments, the controller 111 may be configured to determine a magnitude of power to be supplied to the showerhead, clamping electrodes, and blocking electrodes, and provide commands to the RF power supply 132. In addition to controlling the RF power supply 132, the controller 111 may also be operatively coupled to a gas distribution system 177 and may be configured to provide commands thereto to supply a prescribed amount of processing gas towards the wafer.

In some embodiments, gas distribution system 177 may be coupled to one or more gas sources and include one or more corresponding valves or other flow control components (e.g., mass flow controllers and/or liquid flow controllers). In some embodiments, controller 111 may be connected to the one or more valves or other flow control components to cause them to switch states and thereby allow different gases or combinations of gases to be flowed at different times and/or flow rates. In some embodiments, the one or more gas sources may be fluidically connected to a mixing vessel to allow for blending and/or conditioning of process gases prior to flow over the wafer.

In some embodiments, the RF power supply 132 may be a radio frequency (RF) energy source or other source of energy capable of supplying power to and energizing electrodes to form an electric field. In some exemplary embodiments, the RF power supply 132 may include an RF generator (not shown) that is configured to operate at a desired frequency. For example, the RF generator may be configured to operate within a frequency range of 0.2 MHz to 20.0 MHz. In some exemplary embodiments, the RF generator may operate at 13.56 MHz. In some exemplary embodiments, the RF power supply 132 may include matching network 130 disposed between the RF generator and one or more elements described herein, e.g., the plasma generator system or ESC 102. The matching network 130 may be an impedance matching network that is configured to match an impedance of the RF generator to an impedance of electrodes connected to the RF generator. In this regard, the matching network 130 may be made up of a combination of components, such as a phase angle detector and a control motor; however, in other embodiments, it will be appreciated that the matching network may include other or additional components as well.

As noted above, a wafer may have non-uniformities from processing operations. Various designs of the ESC 102, and in particular various designs and modes (e g., bipolar, monopolar) of the clamping electrodes and/or blocking electrodes, may reduce such non-uniformities, and in particular non-uniformities that correspond to the clamping and/or blocking electrodes.

In some embodiments, ESCs, including ESC 102, may be manufactured using a sintering process. The clamping electrodes 106, 107 and the blocking electrode 108, as well as other elements in the pedestal/ESC 102 and electrical connectors, e.g., metal wires, may be positioned in a powder that may be heated and/or compressed to sinter the powders together, forming a pedestal having the components noted above embedded within. The powder may be a ceramic, e.g., alumina or alumina nitride, that forms a single piece during sintering. In some embodiments, the powder may be in an “unfired” state that may be easily machinable. An ESC may be built by layering components and powder together and then firing the entire ESC to sinter the ceramic powder. As the sintering process results in expansion and contraction of various elements in the pedestal and thus movement of those elements (and potential defects due to such movement), manufacturing may be simplified by aligning components in fewer planes. Thus, clamping electrodes 106, 107 and the blocking electrode 108 may be co-planar to reduce manufacturing costs. Furthermore, connections to the components, e.g., electrical connections to the clamping electrodes 106, 107 and the blocking electrode 108, may be positioned along a vertical central axis to reduce manufacturing complexity.

FIGS. 2A-2C are illustrations of example configurations of electrode pairs, according to some embodiments. FIG. 2A depicts a perspective view of a pair of “D-shaped” electrodes. In some embodiments, the pair of electrodes include a first electrode 202 and a second electrode 204 that are coplanar. First electrode 202 and second electrode 204 may be examples of the clamping electrodes 106 and 107 shown in FIG. 1. FIG. 2B depicts a top-down view of a pair of concentric electrodes. In some embodiments, the concentric electrodes include a first electrode 206 and a second electrode 208. The first electrode 206 may encircle the second electrode 208. FIG. 2C depicts a top-down view of a pair of interdigitated electrodes. In some embodiments, the interdigitated electrodes include a first electrode 210 and a second electrode 212 having a particular shape that allows them to be disposed relative to each other in an interlocking or interleaving fashion without making physical contact.

In some implementations, pairs of electrodes—e.g., the first and second electrodes—may operate in a monopolar mode in which both electrodes have the same voltage and polarity. In some implementations, the first and second electrodes may operate in a bipolar mode in which one electrode has an opposing polarity to the other electrode (e.g., −500V and +500V). In some implementations, the pairs of electrodes may have a respective power source electrically connected thereto. More specifically, a first electrode may be powered by a first power source, and a second electrode may be powered by a second power source.

In some implementations, the pairs of electrodes may be electrically coupled to one power source. That is, the first and second electrodes may be electrically connected to a single power source, and the single power source may power the electrodes in monopolar configuration some of the time and in a bipolar configuration at some other times. However, in some implementations, multiple power supplies may power the electrodes in monopolar configuration some of the time and in a bipolar configuration at some other times, as alluded to above.

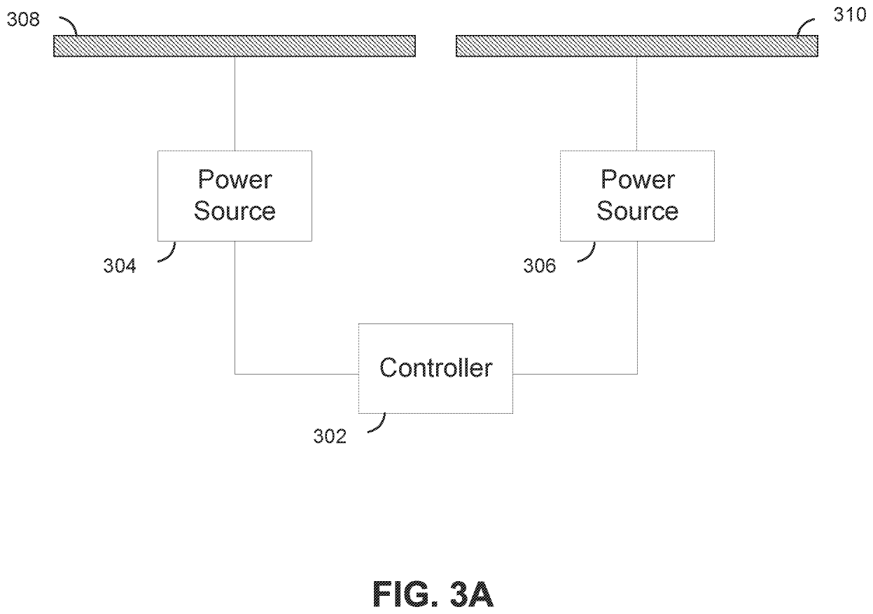

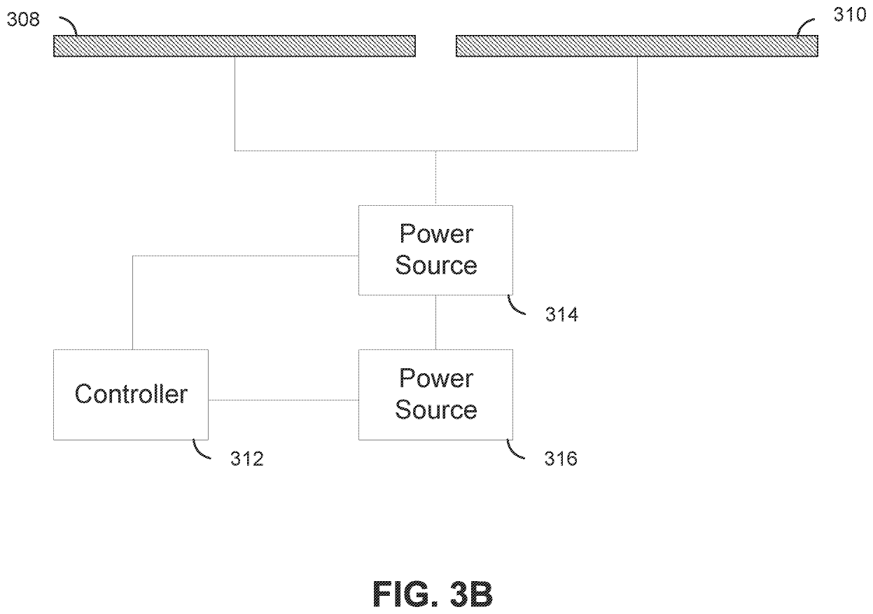

FIGS. 3A and 3B are block diagrams illustrating configurations of electrical coupling of electrodes of an ESC and power sources, according to some embodiments.

In some embodiments, at least one controller 302 may be in communication with a plurality of power sources 304, 306. Such a controller may be configured to determine operational parameters for the power sources and/or the electrode(s) powered by the power source, and provide signals representative of the operational parameters to the power sources so as to cause the power source to generate and provide power according to the operational parameters. Examples of operational parameters include voltage, power, and current driven by the power source. In some embodiments, at least a first power source and a second, separate power source may be coupled to respective clamping electrodes. For example, a first clamping electrode 308 (such as clamping electrode 106 as shown in FIG. 1) may be coupled to the first power source 304, and a second clamping electrode 310 (such as clamping electrode 107) may be coupled to the second power source 306. In some embodiments, the power supplies may be connected in parallel as depicted in FIG. 3A.

In some embodiments, the power supplies may be connected serially as depicted in FIG. 3B, with clamping electrodes 308, 310 both coupled to a first power source 314, which is in turn coupled to a second power source 316 serially with the first power source. At least one controller 312 may be in communication with the power sources 314, 316.

In some embodiments, the at least one controller may be configured to provide operational parameters to at least the first and second power supplies to allow the respectively associated clamping electrodes to operate either in (i) a bipolar mode, where the electrical potentials at the first and second clamping electrodes are opposite, and/or (ii) a monopolar mode, where both the first and second clamping electrodes have an identical electrical potential. In the bipolar mode, the first power source may deliver a voltage of −500 V to the first clamping electrode, and the second power source may deliver a voltage of +500 V to the second clamping electrode. In the monopolar mode, both the first and second power supplies may deliver an identical voltage (e.g., +500 V).

In some embodiments, to minimize stress on components (e.g., circuits, clamping electrodes) that switching may cause, soft start circuitry may be used with the power sources. Such circuitry may include active and passive devices that facilitate bleeding voltage down before ramping the voltage up to the inverted value. In some embodiments, overload protection may also be used, e.g., a circuit breaker, a fuse (e.g., thermistor, thermal fuse), or a current limiting circuit.

In some embodiments, at least a third power source may be coupled to at least one of the clamping electrodes. Variants of the aforementioned parallel and serial configurations, and three-source configurations will be discussed in more detail below.

Advantageously, having electrodes powered by separate power sources obviates the use of a mechanical switch, since switching between high voltages may require the use of a snubber, which is a voltage-suppressing circuit used to suppress voltage spikes caused when a switch opens. Moreover, a sudden change in polarity or electric potential from a switching between modes may cause an arcing discharge with any existing plasma in the process chamber. Further, the controller coupled to the power supplies may determine precise voltage levels such that a transition can occur between the bipolar and monopolar modes, including in response to conditions of the process chamber (e.g., unintended plasma extinguishments), to prevent sudden discharges. Hence, the process chamber may be stabilized by usage of separate power sources.

As noted above, the controller may be configured to instruct the first and second power supplies to provide the appropriate voltages via the aforementioned operational parameters. In some implementations, to prevent an imbalance in average bias across the electrodes, both power supplies may be set to 0 V to turn off the clamping first, while plasma is present to prevent any arcing discharges and to facilitate dechunking of the wafer.

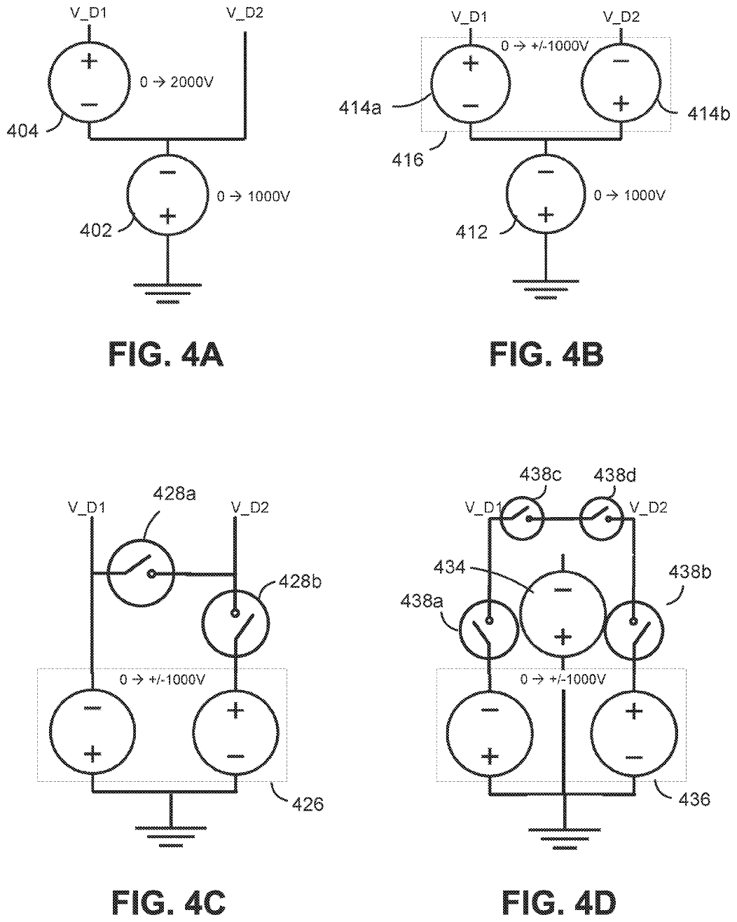

However, certain implementations may use a power supply topology in which a single power source configured to cause the appropriate voltages in a bipolar mode (providing opposing voltages to respective clamping electrodes) or a monopolar mode (having a single clamping electrode). Such a singular power source may be a transformer configured to, for example, supply half of a total voltage via two “legs” separated by a center tap (indicated for example by “+/−1000 V” in FIGS. 4B-4D). In some implementations, a DC step-up (boost) controller or regulator may be used for differential voltage generation.

In some embodiments, a field-effect transistor (FET) may be used for switching signals to two (or more) clamping electrodes or to two (or more) power sources. In some implementations, a metal-oxide-semiconductor FET (MOSFET) may be used. A FET is typically a three-terminal circuit with Gate (G), Source(S), and Drain (D) terminals. By virtue of a very high input (Gate) resistance, the FET may act as a switch that is on (Drain current flows) when the voltage across Gate and Switch (V_{GS}) is made appropriately positive, e.g., above a threshold voltage (V_{GS}>V_{TH}), and that is off when V_{GS}=0 or V_{GS}<V_{TH}. Such a FET may enable a controller or circuit to switch high currents or high voltage loads. In some implementations, a plurality of FETs may be disposed in parallel. A FET may be a depletion-type FET, where it conducts current across the Drain-Source terminal in the absence of voltage to the Gate terminal. In some implementations, the MOSFET may be an enhancement-type MOSFET (where current is conducted across the Source-Drain region only if voltage is applied to the Gate terminal) or a depletion-type MOSFET.

FIGS. 4A-4D are circuit diagrams illustrating different configurations of power sources for use with clamping electrodes, according to some embodiments disclosed herein. Each of these configurations couples to a plurality (e.g., two) of electrodes via power source terminals identified as V_D1 and V_D2. For example, a first clamping electrode may be coupled to at least power source terminal V_D1, and a second clamping electrode may be couple to at least power source terminal V_D2.

FIG. 4A shows an arrangement of a first monopolar power source 402 and a second monopolar power source 404 coupled to the first monopolar power source 402, where each power source is configured to provide a maximum DC voltage. Each power source is a voltage source and may be referred to as such. The first monopolar power source 402 and the second monopolar power source 404 may be coupled to a controller (e.g., as shown in FIG. 3A) configured to cause one or more of the first monopolar power source 402 or the second monopolar power source 404 to ramp up or down in voltage. In one example configuration of FIG. 4A, the first monopolar power source 402 may be ramped up to −2000 V to one clamping electrode (at V_D1) while plasma is present in the processing chamber to effectuate a monopolar clamping mode. In another example configuration, the first monopolar power source 402 may be ramped up to −1000 V, and the second power source 404 may be ramped up to +1000 V to effectuate a bipolar clamping mode using a plurality (e.g., two) of clamping electrodes (at V_D1 and V_D2).

FIG. 4B shows an arrangement of a monopolar power source 412 and a bipolar power source 416 coupled to the monopolar power source 412 serially. The bipolar power source 416 may include a plurality (e.g., two) of voltage sources 414a, 414b connected in parallel to each other. The monopolar power source 412 and the bipolar power source 416 may be coupled to a controller (e.g., as shown in FIG. 3B) configured to cause one or more of the monopolar power source 412 or the bipolar power source 416 to ramp up or down in voltage. In one example configuration of FIG. 4B, the monopolar power source 412 may be ramped up to −1000 V, and the voltage sources 414a, 414b may be supplied with voltage from the monopolar power source 412 such that both electrodes (at V_D1 and V_D2) provide the same voltage to a clamped substrate, thereby effecting monopolar clamping. In another example configuration, the voltage sources 414a, 414b may supply +1000 V and −1000 V to the electrodes at V_D1 and V_D2, respectively, to effectuate a bipolar clamping mode.

FIG. 4C shows an arrangement of a bipolar power source 426 coupled to a plurality (e.g., two) of high-voltage (HV) switches 428a, 428b. In some embodiments, the HV switches may include a FET as described above. In one example configuration of FIG. 4C, the switches 428a, 428b may be provided a small threshold voltage or not provided a voltage across Gate and Switch (Vas) to enable or disable voltage from flowing to one or more clamping electrodes via V_D1, V_D2, or both.

FIG. 4D shows a bipolar power source 436 and a monopolar power source 434 to respective ones of a plurality (e.g., four) of HV switches 438a, 438b, 438c, 438d, which may supply power to one or more clamping electrodes according to state of the switches. In some embodiments, the HV switches may include a FET. In some cases, the additional power source such as in the FIG. 4D configuration may enable multiple stages of ramping up or down, which may reduce the stress on the components. For example, V_D1 and V_D2 may receive +500 V and −500 V from the bipolar power source 436 in a bipolar clamping mode. To switch from bipolar clamping mode to monopolar clamping mode, the monopolar power source 434 may be enabled while the bipolar power source 436 is disabled, by closing switches 438a and 438b and opening switches 438c and 438d. Voltage may thereby be partially reduced for the clamping electrodes, at −250 V each. Thereafter, either switch 438c or 438d may be closed to supply power to just one of the clamping electrodes, at −500 V.

In some embodiments, aforementioned soft start circuitry or overload protection may be used in conjunction with the configurations to minimize stress or overload on components that switching, or ramping up or down in voltage, may cause.

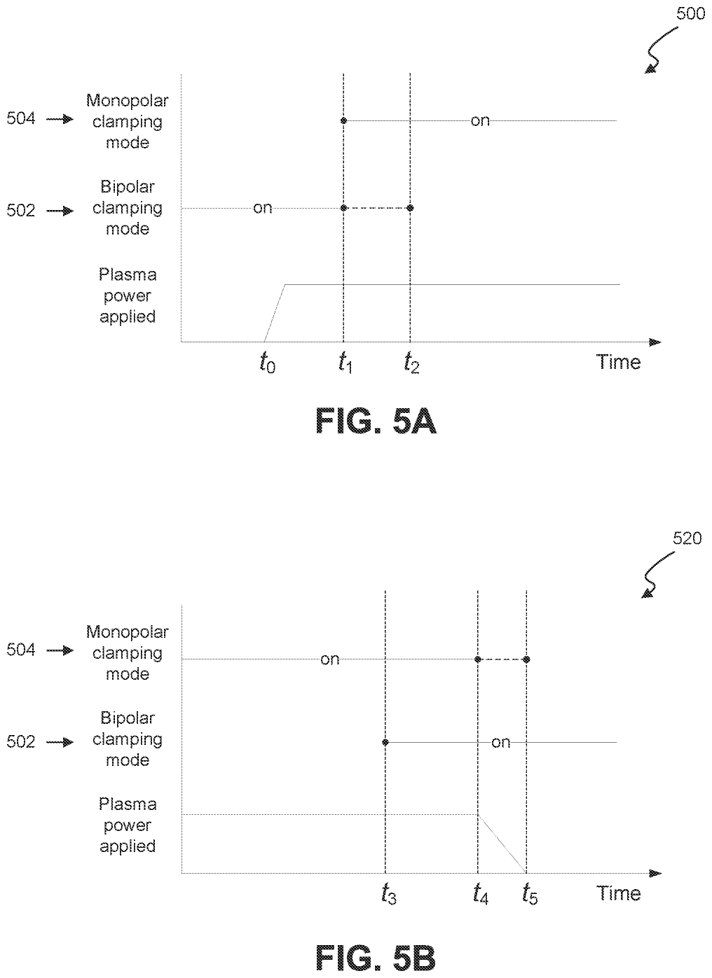

FIG. 5A is an example timing sequence diagram 500 showing activation states of an ESC using a multi-modal configuration, according to some embodiments. In some embodiments, the ESC may be in a bipolar clamping mode 502, utilizing a plurality of clamping electrodes (such as clamping electrodes 106 and 107) having opposing polarities, or a monopolar clamping mode 504, which utilizes the plurality of clamping electrodes having the same polarity. In some embodiments, the ESC may switch between the bipolar clamping mode 502 and the monopolar clamping mode 504, and vice versa, as discussed elsewhere above.

The example timing sequence diagram 500 indicates that the bipolar clamping mode 502 is initially active, and the monopolar clamping mode 504 is not initially active. At a certain time (to), plasma power may be applied (e.g., by a plasma generation system) to form plasma (e.g., within a process chamber in which the ESC is located). Before to, plasma is not present in the process chamber. Between t₀ and t₁, plasma may have been formed. In some cases, initially operating the ESC in the bipolar clamping mode 502 before the plasma strike may reduce the risk of discharging the surface of a substrate.

In some embodiments, the ESC may switch from bipolar to monopolar clamping mode at t₁ when plasma is present in the substrate processing environment (e.g., the process chamber 100). While bipolar clamping may occur with or without the presence of plasma, monopolar clamping involves interaction with plasma; thus monopolar clamping mode 504 may be activated sometime after plasma is ignited, e.g., after t₀ or at t₁. In some cases, t₁ may occur immediately after t₀. In some cases, t₁ may occur after a prescribed time (e.g., milliseconds or seconds) after t₀. At t₁, bipolar clamping mode 502 may end, and monopolar clamping mode 504 may begin. The switch from bipolar to monopolar clamping mode may include changing the voltage and polarity of one of the clamping electrodes to match the other clamping electrode, e.g., from −500 V to +500 V, to turn both electrodes into the same polarity. In some implementations, the voltage may transition rather than immediately change, resulting in the bipolar clamping mode 502 ending at some time after t₁, e.g., at t₂. The monopolar clamping mode 504 may continue as long as plasma power is applied or when transitioning to bipolar clamping mode 502, e.g., between t₄ and t₅ as discussed with respect to FIG. 5B. Note that the time values mentioned with respect to FIG. 5A are not to scale and may represent arbitrary relative temporal positions.

FIG. 5B is an example timing sequence diagram 520 showing activation states of an ESC using a multi-modal configuration, according to some embodiments. In some embodiments, the ESC may initially be in a monopolar clamping mode 504. In some cases, the monopolar clamping mode 504 may have been activated according to the example timing sequence diagram 500. In some cases, the monopolar clamping mode 504 may have been initiated near the time of activation. In both types of cases, plasma has been ignited in the process chamber and the substrate has been exposed to plasma, allowing the use of monopolar clamping mode 504. Monopolar clamping may beneficially reduce discharge issues and parasitic plasma associated with bipolar clamping.

In some embodiments, the ESC may switch from monopolar clamping mode 504 to bipolar clamping mode 502. For example, bipolar clamping mode 502 may be activated at t₃, when plasma has not been extinguished yet (e.g., plasma power is still being applied). Slightly after t₃, e.g., at t₄, plasma power may discontinue, and monopolar clamping mode 504 may cease. In some cases, plasma may still persist in the process chamber after plasma power has discontinued. Hence, in some implementations, the monopolar clamping mode 504 may cease sometime after t₄, e.g., at t₅. The bipolar clamping mode 502 may continue as long as plasma power is not being applied or when transitioning to monopolar clamping mode 504, e.g., between t₀ and t₁. Note that the time values mentioned with respect to FIG. 5B are not presented to scale and may represent arbitrary relative temporal positions.

In some embodiments, the switch to bipolar clamping mode 502 may correspond to timing associated with plasma extinguishment. That is, it may be known to a plasma generation system that plasma power will no longer be applied at, e.g., t₄. In some implementations, a controller may signal to the plasma generation system to discontinue the application of plasma power, e.g., at t₄, as designed or intended. In some cases, plasma extinguishment may be unintended. In some implementations, one or more components (e.g., a visual-inertial sensor) of the process chamber, including at the ESC, may detect the presence of plasma. In some implementations, a plasma emission detector may detect a parameter relating to the presence of plasma, e.g., composition of the plasma, or concentration of one or more plasma species. In some implementations, voltage and/or current sensors may monitor a voltage, a current, or another parameter based on either or both (e.g., V/I) of the RF power delivered, e.g., to the plasma generator system, to determine the plasma state. In some implementations, the flow of gases (e.g., flow rates) may be monitored by, e.g., the mass flow controller of the gas distribution system 177.

Responsive to detecting that the parameter is below or does not meet a desired threshold (e.g., the presence of plasma or a species or a gas, or a flow rate or the state of the mass flow controller of the gas distribution system 177), the ESC may be switched to bipolar clamping mode 502 from monopolar clamping mode 504, so as to prevent discharge or to keep the wafer clamped and stabilized, preventing sliding or dislodging from the ESC or pedestal. This switch may occur independent of any signals transmitted (e.g., by a controller) to reduce plasma power, e.g., during unintended plasma extinguishment.

Similarly, in some embodiments, prior to the switch to monopolar clamping mode 504 (according to, e.g., timing sequence diagram 500 shown in FIG. 5A), it may be anticipated or known to a plasma generation system that plasma power will be applied at, e.g., to. Based thereon, and/or based on the presence of plasma, the ESC may be switched from bipolar clamping mode 502 to monopolar clamping mode 504.

Thus, in embodiments, the bipolar clamping mode of the ESC and the application of plasma power may overlap in part, and the monopolar clamping mode of the ESC and the application of plasma power may overlap completely.

### Methods

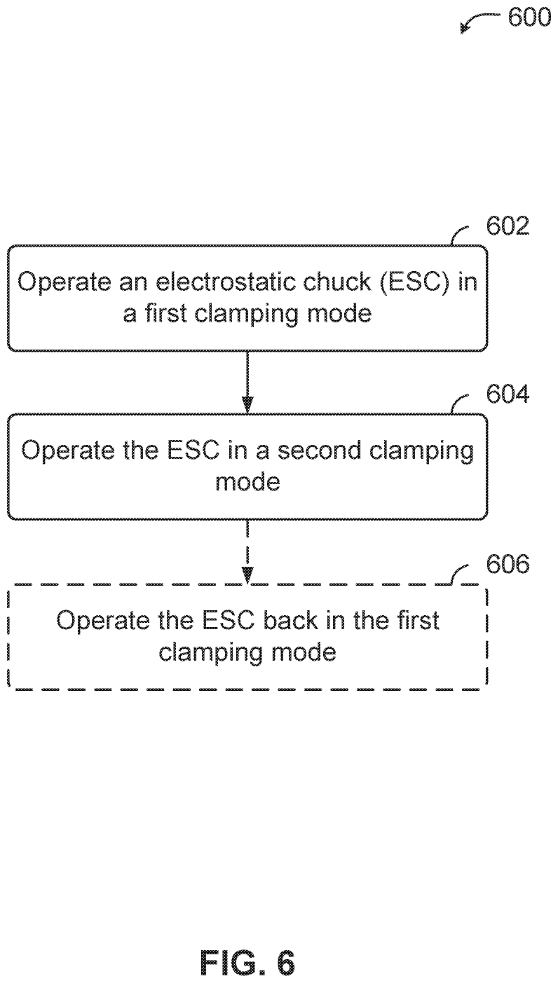

FIG. 6 is a flow diagram illustrating a method 600 for operating an electrostatic chuck (ESC), according to some embodiments. One or more of the functions of the method 600 may be performed by a computerized apparatus or system. Means for performing the functionality illustrated in one or more of the steps shown in FIG. 6 may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or another apparatus to perform the operations. A controller may be one example of the computerized apparatus or system. An ESC may be another example of the computerized apparatus or system. A process chamber may be another example of the computerized apparatus or system. Example components of a process chamber (including a controller) and an ESC are illustrated in FIG. 1, which are described in more detail above.

It should also be noted that the operations of the method 600 may be performed in any suitable order, not necessarily the order depicted in FIG. 6. Further, the method 600 may include additional or fewer operations than those depicted in FIG. 6 to perform the operation of the ESC.

At step 602, the method 600 may include operating an electrostatic chuck (ESC) in a first clamping mode. In some embodiments, the ESC may be an example of ESC 102 as shown in FIG. 1. In some embodiments, the ESC may include a plurality of clamping electrodes, such as the clamping electrodes 106 and 107 as shown in FIG. 1. In some configurations, the ESC may use a pair of clamping electrodes configured to have high voltages in opposing polarities or the same polarity. For example, during operation of the ESC, a first of the pair of clamping electrodes may have a voltage of −500 V, and a second of the pair of clamping electrodes may have a voltage of +500 V. In some configurations, both clamping electrodes may have a voltage of +500 V.

When the clamping electrodes have opposing polarities, the ESC may be considered to be operating in a bipolar clamping mode. When the clamping electrodes have the same polarity, the ESC may be considered to be operating in a monopolar clamping mode. In some cases, plasma will have been ignited in the process chamber in which the ESC is situated, which may allow usage of the clamping electrodes in the same polarity, and usage of the ESC in the monopolar clamping mode.

In some implementations, the operating of the ESC in the first clamping mode may include operating the ESC in the bipolar clamping mode. The bipolar clamping mode may be effectuated using any one of the configurations described above with respect to FIGS. 4A-4D. In some implementations, the operating of the ESC in the first mode may include operating the ESC in the monopolar clamping mode. The monopolar clamping mode may be effectuated using any one of the configurations (different from the configuration used to effectuate the bipolar clamping mode) described above with respect to FIGS. 4A-4D. In some cases, the bipolar or the monopolar clamping mode may be the initial mode during activation of a substrate, e.g., a wafer on which processing and operations may take place. In some cases, the bipolar or the monopolar clamping mode may have been switched from a previous monopolar or bipolar clamping mode.

In some embodiments, the first clamping mode includes clamping a substrate to the ESC using bipolar clamping or monopolar clamping.

At step 604, the method 600 may include operating the ESC in a second clamping mode. In some embodiments, the operating in the second clamping mode may be based at least on a change in a substrate processing environment (e.g., process chamber 100). In some implementations, the operating the ESC in the second clamping mode may include switching from the first clamping mode during operation of the ESC in the first clamping mode. As seen in FIGS. 5A and 5B, there may be a period of time in which there is an overlap of operation of the first and second modes. In some embodiments, the change to the second clamping mode may be accomplished via the use of multiple power sources. For example, the configurations described with respect to in FIGS. 2 and 3 may allow transition between bipolar and monopolar clamping modes using the plurality of electrodes. In some cases, the second clamping mode may occur some time after the change in the substrate processing environment. As examples of the change in the substrate processing environment, referring back to FIGS. 5A and 5B, it may be the case that plasma strike occurs at t₀, or plasma extinguishment occurs at t₄, but monopolar clamping may occur at t₁ (after t₀), and bipolar clamping may occurs at t₃ (before t₄) to ensure that monopolar clamping is being used when plasma is present.

In some embodiments, the substrate processing environment may include the presence of plasma, a composition of the plasma, and/or a concentration of one or more plasma species. If the substrate processing environment changes, e g., an increase in plasma is detected, the ESC may switch to operate in the second clamping mode. In some implementations, a monopolar clamping mode may be appropriate in the presence of plasma. Hence, in said implementations, the operating of the ESC in the second clamping mode may include operating the ESC in the monopolar clamping mode, switched from bipolar clamping mode as the first clamping mode. Monopolar clamping may better assure uniformity of the substrate, and reduce risks of damage to chamber components and formation of parasitic plasma.

If the plasma is extinguished, the ESC may switch to a bipolar clamping mode. Bipolar clamping may reduce declamping risks associated with monopolar clamping. Hence, in some implementations, the operating of the ESC in the second clamping mode may include operating the ESC in the bipolar clamping mode, switched from monopolar clamping mode as the first clamping mode.

In some embodiments, the second clamping mode includes clamping a substrate to the ESC using bipolar clamping or monopolar clamping, other than that used in the first clamping mode.

In some embodiments, the change in the substrate processing environment may include a signal from a controller. A controller (e.g., controller 111, 302, 312) may provide instructions to one or more power sources to provide the appropriate voltages.

In some embodiments, the basis in the change in the substrate processing environment may include anticipated future change in the substrate processing environment. For instance, in a processing cycle where plasma is introduced or removed in predefined intervals or repeating steps, or in a processing step with a predefined exposure length to plasma by the substrate, or depending on the type or characteristic of film formed or wafer used, it may be known that monopolar or bipolar clamping may be better suited to clamp the substrate during a particular portion of the process.

Timing of the change between bipolar and monopolar clamping modes can be seen in FIGS. 5A and 5B. Note that bipolar clamping may occur with or without the presence of plasma. However, monopolar clamping involves the presence of plasma. According to various embodiments, the operation of the ESC in the second clamping mode may occur while plasma is present. In some cases, the first and second clamping modes may be active simultaneously during an overlapping period of time (e.g., between t₁ and t₂ or between t₃ and t₄ or t₅) to enable a transition period rather than a sudden change in clamping mode.

Optionally, at step 606, the method 600 may proceed to operate the ESC in the first clamping mode. In some embodiments, the operation of the ESC may switch back to the first clamping mode based at least on another change in the substrate processing environment. The switching back may occur during operation in the second clamping mode. In some embodiments, the change in the substrate processing environment may be the reverse of that for step 604. For example, a decrease in plasma may be detected or anticipated.

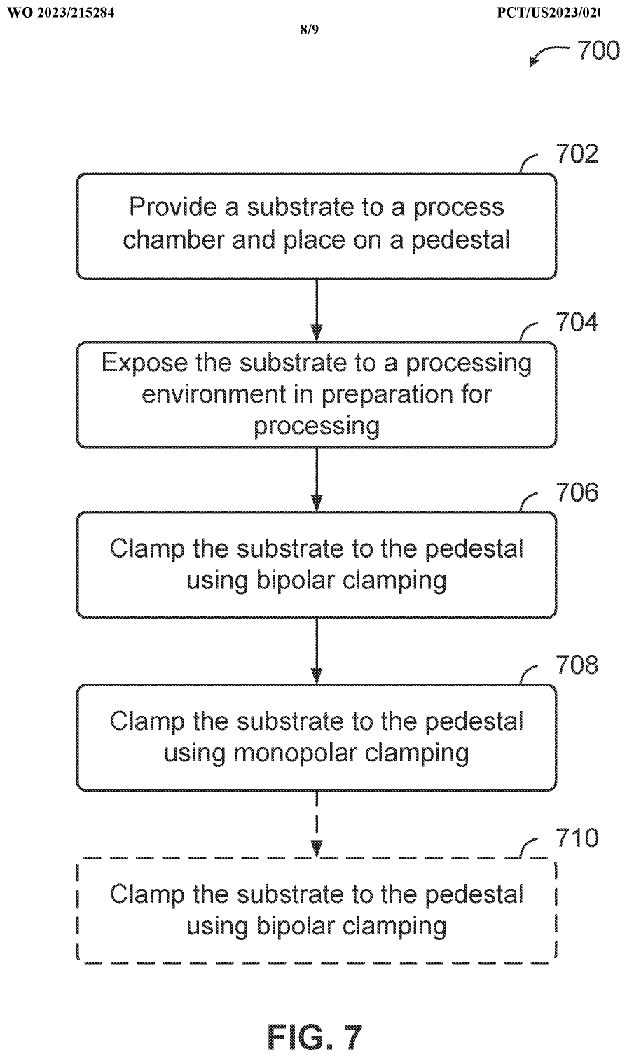

FIG. 7 is a flow diagram illustrating another method 700 for operating an electrostatic chuck (ESC), according to some embodiments. One or more of the functions of the method 700 may be performed by a computerized apparatus or system. Means for performing the functionality illustrated in one or more of the steps shown in FIG. 7 may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or another apparatus to perform the operations. A controller may be one example of the computerized apparatus or system. An ESC may be another example of the computerized apparatus or system. A process chamber may be another example of the computerized apparatus or system. Example components of a process chamber (including a controller) and an ESC are illustrated in FIG. 1, which are described in more detail above.

It should also be noted that the operations of the method 700 may be performed in any suitable order, not necessarily the order depicted in FIG. 7. Further, the method 700 may include additional or fewer operations than those depicted in FIG. 7 to perform the operation of the ESC.

At step 702, the method 700 may include providing a substrate to a process chamber and placing the substrate on a pedestal. In some embodiments, the substrate may include a silicon-based or other semiconductor wafer on which operations may be performed, and the process chamber may be an example of the process chamber 100 described with respect to FIG. 1. In some embodiments, the pedestal may include an electrostatic chuck (ESC).

At step 704, the method 700 may include exposing the substrate to a substrate processing environment in preparation for processing. In some embodiments, the substrate processing environment may include a plasma formed about the substrate, e.g., above the wafer.

At step 706, the method 700 may include clamping the substrate to the pedestal using bipolar clamping. In some embodiments, the bipolar clamping may be performed using two electrodes, such as the electrodes as depicted in FIG. 1, 2, 3A or 3B. In some implementations, multiple power sources may be utilized as depicted in FIGS. 3A and 3B to effectuate the bipolar clamping. For example, two power supplies electrically coupled to respective electrodes may power the respective electrodes by providing voltages with opposing polarities.

At step 708, the method 700 may include clamping the substrate to the pedestal using monopolar clamping. In some embodiments, the clamping of the substrate using the monopolar clamping may be based at least on a change in the substrate processing environment. In some implementations, the using of monopolar clamping may include switching from bipolar clamping during an operation of the ESC using the bipolar clamping. As seen in FIGS. 5A and 5B, there may be a period of time in which there is an overlap of operation of the bipolar and monopolar modes. In some embodiments, the change in the substrate processing environment may include an introduction of plasma in the processing chamber, e.g., plasma strike occurs, is detected, or is anticipated. In some cases, the monopolar clamping may occur some time after the change in the substrate processing environment. For example, referring back to FIG. 5A, it may be the case that plasma strike occurs at to, but monopolar clamping occurs at h (after to) to ensure that plasma is present before switching to monopolar clamping which involves the presence of plasma.

In some embodiments, the monopolar clamping may be performed using two electrodes. In some embodiments, the monopolar clamping may be performed using one electrode (e.g., an outer electrode of two concentric electrodes may be powered but not an inner electrode). In some implementations, multiple (e.g., two) power sources may be utilized. In some implementations, one power source may be utilized.

Optionally, at step 710, the method 700 may include clamping the substrate to the pedestal using bipolar clamping. In some embodiments, this may be based at least on another change in the substrate processing environment. In some embodiments, the change in the substrate processing environment may be the reverse of that for step 708. For example, a decrease in plasma may occur (e.g., extinguishment), or be detected or anticipated.

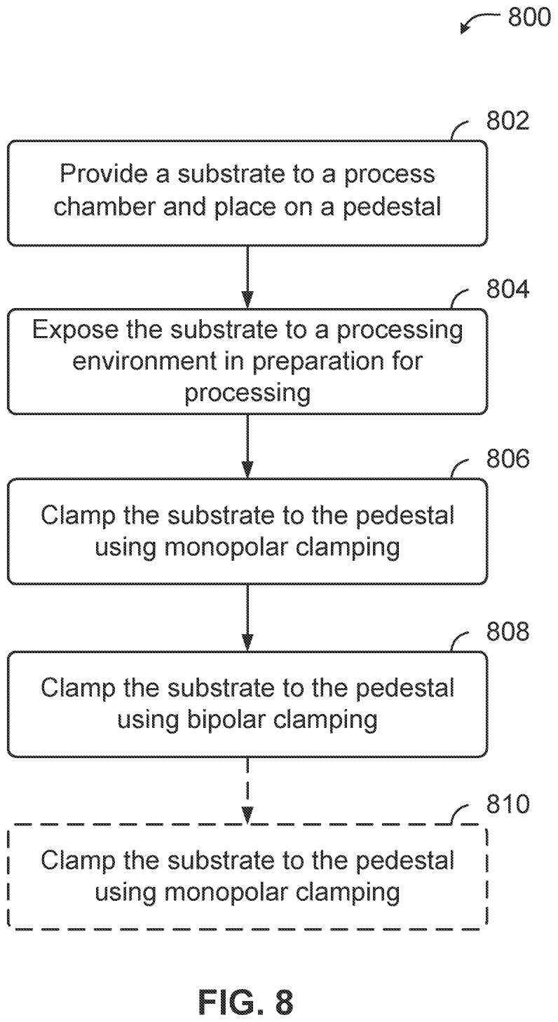

FIG. 8 is a flow diagram illustrating another method 800 for operating an electrostatic chuck (ESC), according to some embodiments. One or more of the functions of the method 800 may be performed by a computerized apparatus or system. Means for performing the functionality illustrated in one or more of the steps shown in FIG. 8 may include hardware and/or software components of such computerized apparatus or system, such as, for example, a controller apparatus, a computerized system, or a computer-readable apparatus including a storage medium storing computer-readable and/or computer-executable instructions that are configured to, when executed by a processor apparatus, cause the at least one processor apparatus or another apparatus to perform the operations. A controller may be one example of the computerized apparatus or system. An ESC may be another example of the computerized apparatus or system. A process chamber may be another example of the computerized apparatus or system. Example components of a process chamber (including a controller) and an ESC are illustrated in FIG. 1, which are described in more detail above.

It should also be noted that the operations of the method 800 may be performed in any suitable order, not necessarily the order depicted in FIG. 8. Further, the method 800 may include additional or fewer operations than those depicted in FIG. 8 to perform the operation of the ESC.

At step 802, the method 800 may include providing a substrate to a process chamber and placing the substrate on a pedestal. At step 804, the method 800 may include exposing the substrate to a processing environment in preparation for processing. Steps 802 and 804 may correspond to and involve substantially similar operations as steps 702 and 704.

At step 806, the method 800 may include clamping the substrate to the pedestal using monopolar clamping. In some cases, fabrication process with the substrate may begin by striking a plasma in the process chamber before the substrate is clamped. In such cases, either bipolar or monopolar clamping may be used. That said, in some embodiments, monopolar clamping may be used, e.g., depending on the type of film or wafer used (e.g., wafer is susceptible to non-uniformity issues), or to reduce power usage if a one-electrode configuration is used. In some embodiments, multiple (e.g., two) electrodes may be used for monopolar clamping (e.g., the same voltage may be applied to each electrode). In some embodiments, respective power sources may be used to power each of the multiple (e.g., two) electrodes.

However, in some embodiments, a single electrode may be used to effectuate the monopolar clamping. In some embodiments, a single power source may be used. In some implementations, the single power source may be used to power a single electrode or multiple (e.g., two) electrodes.

At step 808, the method 800 may include clamping the substrate to the pedestal using bipolar clamping. In some embodiments, the clamping of the substrate using the bipolar clamping may be based at least on a change in the processing environment. In some implementations, the using of bipolar clamping may include switching from monopolar clamping during an operation of the ESC using the monopolar clamping. As seen in FIGS. 5A and 5B, there may be a period of time in which there is an overlap of operation of the bipolar and monopolar modes. In some embodiments, the change in the processing environment may include a removal of plasma in the processing chamber, e.g., plasma extinguishment occurs, is detected, or is anticipated. In some cases, the bipolar clamping may occur some time before the change in the processing environment. For example, referring back to FIG. 5B, it may be the case that plasma extinguishment occurs at t₄, but bipolar clamping occurs at t₃ (before t₄) to ensure, e.g., that arcing discharge does not occur while the wafer is still clamped, or that the wafer does not slide.

In some embodiments, the bipolar clamping may be performed using two electrodes. In some implementations, multiple (e.g., two) power sources may be utilized. In some implementations, one power source may be utilized.

Optionally, at step 810, the method 800 may include clamping the substrate to the pedestal using monopolar clamping. In some embodiments, this may be based at least on another change in the processing environment. In some embodiments, the change in the processing environment may be the reverse of that for step 808. For example, an increase in plasma may occur (e.g., plasma strike), or be detected or anticipated.

In some implementations, a controller (e.g., 111, 302, 312) is part of a system, which may be part of the above-described examples, including a process chamber or another system that includes an ESC. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the processing of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of processing operations, examine a history of past processing operations, examine trends or performance metrics from a plurality of processing operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the processing and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

System and methods have now been provided that provide improved chucking or clamping capabilities over conventional systems. The above-described methods, apparatus, and systems enable a flexible usage of various clamping modes (e.g., bipolar and/or monopolar) as compared to conventional systems, and they do so while using modifications to existing technology. As a result, embodiments the improved chucking systems now include configurations involving one or more power sources.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A system configured to operate an electrostatic chuck (ESC) in a plurality of modes, the system comprising:
a plurality of clamping electrodes associated with the ESC;
a plurality of power sources electrically coupled to the plurality of clamping electrodes;
a controller coupled to the plurality of power sources, wherein the controller is configured to:
clamp a substrate to the ESC using a first clamping mode, the first clamping mode comprising a first configuration of the plurality of clamping electrodes and the plurality of power sources; and
during operation of the ESC using the first clamping mode, switch from the first clamping mode to clamp the substrate to the ESC using a second clamping mode, the second clamping mode comprising a second configuration of the plurality of clamping electrodes and the plurality of power sources, the second configuration being different from the first configuration.

2. The system of claim 1, wherein:
the first clamping mode comprises a bipolar clamping mode; and
the second clamping mode comprises a monopolar clamping mode.

3. The system of claim 1, wherein:
the first clamping mode comprises a monopolar clamping mode; and
the second clamping mode comprises a bipolar clamping mode.

4. The system of claim 3, wherein:
the plurality of clamping electrodes comprises a first clamping electrode and a second clamping electrode;
the plurality of power sources comprises a first power source and a second power source; and
the bipolar clamping mode comprises causing the first power source to supply a first voltage at a first polarity to the first clamping electrode, and causing at least the second power source to supply a second voltage at a second polarity to the second clamping electrode, the second polarity opposing the first polarity.

5. The system of claim 3, wherein:
the plurality of clamping electrodes comprises a first clamping electrode and a second clamping electrode;
the plurality of power sources comprises a first power source and a second power source; and
the monopolar clamping mode comprises causing the first power source to supply a first voltage at a first polarity to the first clamping electrode, and causing at least the second power source to supply the first voltage at the first polarity to the second clamping electrode.

6. The system of claim 1, wherein the switch from the first clamping mode to the second clamping mode is based on a change in a processing environment.

7. The system of claim 6, wherein the change in the processing environment comprises an introduction of plasma within a process chamber.

8. The system of claim 6, wherein the change in the processing environment comprises a signal from the controller.

9. The system of claim 6, wherein:
the change in the processing environment comprises an introduction of plasma in the process chamber; and
the switch from the first clamping mode to the second clamping mode is configured to occur responsive to the introduction of the plasma in the process chamber.

10. The system of claim 9, wherein:
the controller is further configured to, based on a second change in the processing environment, switch from the second clamping mode to clamp the substrate to the ESC using the first clamping mode;
the second change in the processing environment comprises removal of plasma; and
the switch from the second clamping mode to the first clamping mode is configured to occur a period of time prior to the removal of the plasma.

11. A method of operating an electrostatic chuck (ESC) in multiple modes, the method comprising:
operating the ESC in a first clamping mode; and
during a portion of the operation in the first clamping mode, and based on a change in a processing environment, operating the ESC in a second clamping mode;
wherein each of the first clamping mode and the second clamping mode comprises clamping a substrate to the ESC using respective configurations of clamping electrodes associated with the ESC.

12. The method of claim 11, wherein the first clamping mode comprises a bipolar clamping mode of the ESC, and the second clamping mode comprises a monopolar clamping mode of the ESC.

13. The method of claim 12, wherein:
the bipolar clamping mode comprises supplying a first voltage at a first polarity to a first clamping electrode of the ESC, and supplying a second voltage at a second polarity to a second clamping electrode of the ESC, the second polarity opposing the first polarity; and
the monopolar clamping mode comprises supplying the first voltage at the first polarity to the first and second clamping electrodes of the ESC.

14. The method of claim 11, wherein the first clamping mode comprises a monopolar clamping mode of the ESC, and the second clamping mode comprises a bipolar clamping mode of the ESC.

15. The method of claim 14, wherein:
the bipolar clamping mode comprises supplying a first voltage at a first polarity to a first clamping electrode of the ESC, and supplying a second voltage at a second polarity to a second clamping electrode of the ESC, the second polarity opposing the first polarity; and
the monopolar clamping mode comprises supplying the first voltage at the first polarity to the first and second clamping electrodes of the ESC.

16. The method of claim 11, wherein the change in the processing environment comprises an introduction of plasma in the processing environment or a removal of the plasma in the processing environment.

17. An electrostatic chuck (ESC) operable in a substrate processing environment, the ESC comprising:
a first clamping electrode electrically coupled to a first power source; and
a second clamping electrode electrically coupled to a second power source;
wherein the ESC is configured to:
clamp a substrate to the ESC using a first clamping mode; and
during a portion of the first clamping mode, switch to clamp the substrate to the ESC using a second clamping mode;
wherein the first clamping mode comprises a first voltage received at the first clamping electrode from the first power source, and a second voltage received at the second clamping electrode from the second power source, the first and second voltage having opposing polarities; and
wherein the second clamping mode comprises a voltage received at the first clamping electrode from the first power source and the second clamping electrode from the second power source.

18. The ESC of claim 17, wherein the ESC is further configured to clamp the substrate to the ESC using the second clamping mode based at least on a change in the substrate processing environment.

19. The ESC of claim 18, wherein the change in the substrate processing environment comprises an introduction of plasma in the processing environment or a removal of the plasma in the substrate processing environment.

20. The ESC of claim 17, wherein the clamping of the substrate using the second clamping mode is configured to occur a prescribed time before or after a change in the substrate processing environment.
